(19) United States
(12) Patent Application Publication
(10) Pub. No.: US 2013/0152851 A1
(43) Pub. Date: Jun. 20, 2013

(54) Bulk Growth Grain Controlled Directional Solidification Device and Method

(71) Applicants: Tao Li, Pittsford, NY (US); Richard H. Berg, Parma, NY (US); Richard Heckert, Lewisburg, PA (US)

(72) Inventors: Tao Li, Pittsford, NY (US); Richard H. Berg, Parma, NY (US); Richard Heckert, Lewisburg, PA (US)

(73) Assignee: SPX Corporation, Charlotte, NC (US)

(21) Appl. No.: 13/326,642

(22) Filed: Dec. 15, 2011

(51) Int. Cl. C30B 11/02

(52) U.S. Cl. 117/81; 117/223

(57) ABSTRACT

A solidification system is provided and includes a crucible, heater, insulation, movable insulation, and radiation regulator. The crucible is configured to retain a volume of silicon. The heater is to heat the crucible. The heater being configured to provide sufficient heat to melt the volume of silicon. The insulation is to reduce heat loss from a first portion of the crucible. The movable insulation to regulate heat loss from a second portion of the crucible. The radiation regulator is to regulate radiant heat loss over the second portion of the crucible. The radiation regulator is configured to modulate a size of an opening in the radiation regular through which radiant heat dissipates from.

### FIELD OF THE INVENTION

The present invention generally relates to grain-controlled solidification of a material. More particularly, the present invention pertains to a device and method for bulk growth and grain-controlled directional solidification of a material.

### BACKGROUND OF THE INVENTION

It is generally known that silicon (Si) is used in the fabrication of microprocessors and solar cells. Typically the Si used for these purposes is in crystalline form. Polycrystalline Si is relatively easy to produce. However, single-crystal Si is most suitable for these uses due to relatively high concentrations of impurities present in the grain boundaries as compared to the grain bodies. Unfortunately, single-crystal Si is expensive and time consuming to produce. Accordingly, it is desirable to provide a method and device capable of overcoming the disadvantages described herein at least to some extent.

### SUMMARY

The foregoing needs are met, to a great extent, by the present invention, wherein in one respect a solidification system improves the process of crystallizing silicon at least to some extent.

An embodiment of the present invention pertains to a solidification system including a crucible, heater, insulation, movable insulation, and radiation regulator. The crucible is configured to retain a volume of silicon. The heater is configured to heat the crucible. The heater is configured to provide sufficient heat to melt the volume of silicon. The insulation is used to reduce heat loss from a first portion of the crucible. The movable insulation to regulate heat loss from a second portion of the crucible. The radiation regulator is to regulate radiant heat loss over the second portion of the crucible. The radiation regulator is configured to modulate a size of an opening in the radiation regulator through which radiant heat dissipates from.

Another embodiment of the present invention relates to a method of solidifying a volume of silicon. In this method a temperature of the volume of silicon is modulated between a temperature of solidification and a temperature of melting, a first portion of the volume of silicon is insulated, and a size of a radiant heat transmissive opening disposed in cooperative alignment with a second portion of the volume of silicon is modulated.

Yet another embodiment of the present invention pertains to an apparatus for solidifying a volume of silicon. The apparatus includes means for modulating a temperature of the volume of silicon, means for insulating, and means for modulating a size of a radiant heat transmissive opening. The means for modulating a temperature of the volume of silicon is to heat the volume of silicon between a temperature of solidification and a temperature of melting. The means for insulating is to insulate around a first portion of the volume of silicon. The means for modulating a size of a radiant heat transmissive opening is disposed in cooperative alignment with a second portion of the volume of silicon.

There has thus been outlined, rather broadly, certain embodiments of the invention in order that the detailed description thereof herein may be better understood, and in order that the present contribution to the art may be better appreciated. There are, of course, additional embodiments of the invention that will be described below and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of embodiments in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a cross sectional view of a bulk growth grain controlled solidification system according to an embodiment of the invention.

FIG. 2 is a cross sectional view of the bulk growth grain controlled solidification system according to FIG. 1 during a solidification process.

FIG. 3 is a cross sectional view of the bulk growth grain controlled solidification system according to FIG. 1 during the solidification process.

FIG. 4 is a cross sectional view of the bulk growth grain controlled solidification system according to FIG. 1 during the solidification process.

FIG. 5 is a cross sectional view of the bulk growth grain controlled solidification system according to FIG. 1 during the solidification process.

FIG. 6 is a cross sectional view of the bulk growth grain controlled solidification system according to FIG. 1 during the solidification process.

FIG. 7 is a cross sectional view of the bulk growth grain controlled solidification system according to FIG. 1 during the solidification process.

FIG. 8 is a top view of a radiation regulator suitable for use with the bulk growth grain controlled solidification system according to FIG. 1.

FIG. 9 is a top view of the radiation regulator suitable for use with the bulk growth grain controlled solidification system according to FIG. 1 in a partially open conformation.

FIG. 10 is a top view of a radiation regulator suitable for use with the bulk growth grain controlled solidification system according to FIG. 1 in a partially/mostly open conformation.

FIG. 11 is a top view of a radiation regulator suitable for use with the bulk growth grain controlled solidification system according to FIG. 1.

FIG. 12 is a side view of a radiation regulator suitable for use with the bulk growth grain controlled solidification system according to FIG. 1.

FIG. 13 is a top view of the radiation regulator having two shutters according to another embodiment of the invention.

FIG. 14 is a bottom, hidden-line view of the radiation regulator having one shutter according to yet another embodiment of the invention.

FIG. 15 is a flow diagram of a method for solidifying silicon with the system according to FIG. 1.

### DETAILED DESCRIPTION

The present invention provides a mono-crystalline silicon (Si) directional solidification technology that starts with a relatively smaller size seed as compared to conventional solidification technologies. In some embodiments, a directional solidification casting system and a corresponding process are provided. The Si ingot produced by this technique possesses mono-crystalline microstructure with low impurities and long minority-carrier life, which gives rise to an equivalent cell efficiency as mono-crystalline Si manufactured via conventional Czochralski (CZ) process.

Embodiments of this invention provide an accurate control of the thermal conditions affecting crystal nucleation behavior and growth direction/grain size to enhance the silicon ingot quality produced by an industrial directional solidification growth. A variable heat control system allows for adjusting the heat flow through the bottom of the crucible during the solidification. The thermal conditions may be regulated by controlling an amount of radiational/conductive cooling from a surface of crucible bottom and thereby modulate the crystal growth direction in the crucible. In this manner, a relatively small Si seed crystal may be controlled to grow parallel along the crucible bottom surface with the desired crystal structure to fully fill the crucible bottom before the vertical ingot growth. As a result, a mono-crystalline ingot may be grown within the crucible without the need for expensive and time consuming pulling/drawing systems used conventionally.

In a particular embodiment, multiple shutters are opened in a controlled manner to produce an expanding area for radiant heat to escape from the bottom of the crucible. One mechanism can be an iris (similar to an iris aperture of a camera) where one or more shutters or insulating members transverse from the center line of the crucible while maintaining an almost axis symmetric opening for the heat to escape.

Advantages of various embodiments of the invention may include, for example: (1) reduced seed size; (2) reduced equipment cost; (3) increased ingot diameter; and/or (4) improved yield of single crystal silicon.

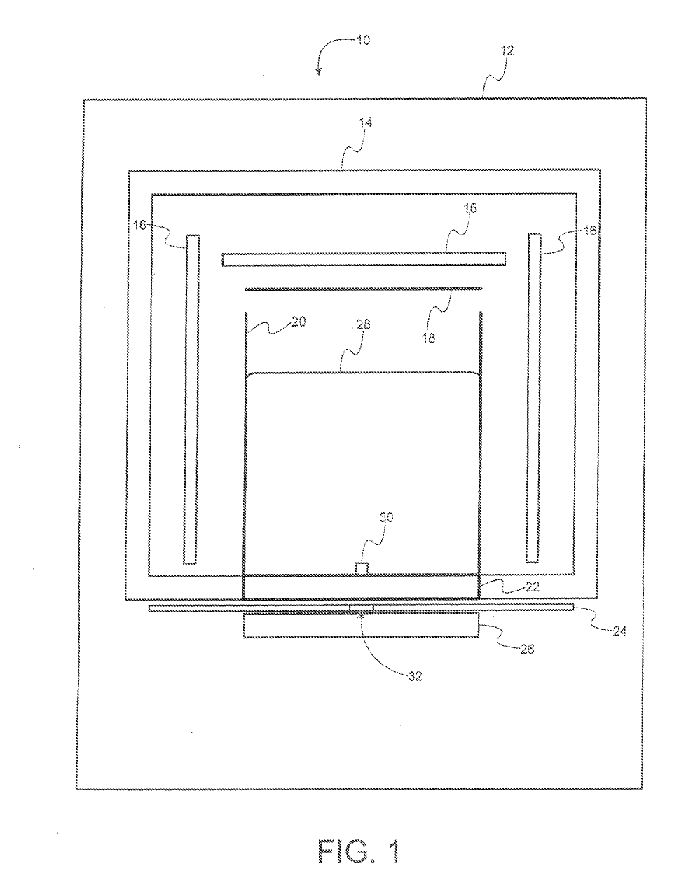

Various embodiments of the invention will now be described with reference to the drawing figures, in which like reference numerals refer to like parts throughout. As shown in FIG. 1 a bulk growth grain controlled solidification system (BGGCSS) 10 includes a furnace chamber 12, an insulation 14, one or more heaters 16, a shield 18, a crucible 20, a heat exchange block 22, a radiation regulator 24, and a movable insulation 26. A volume of silicon (Si) 28 is placed in the crucible 20 and melted via the heaters 16, for example. Of note, the BGGCSS 10 shown in FIGS. 1-10 are simplified and for illustrative purposes only. For example, although the heater 16 is shown extending from the top of the crucible 20 to the bottom, in other examples, two or more heaters may be utilized along the height of the crucible and independently controlled to heat, for example, the bottom, middle, and/or top of the crucible and the contents therein. In another example, a gas/heat inlet/outlet may be included to draw gas in and through the BGGCSS 10 and/or control the flow of heat therein.

Optionally, a Si seed crystal 30 is placed at the bottom center of the crucible 20. As shown in FIG. 1, if the Si seed crystal 30 is placed within the crucible 20, it may be disposed in cooperative alignment with an opening 32 in the radiation regulator 24. In general, the radiation regulator 24 includes a radiant reflective portion and the opening 32 which is a radiant non-reflective or transmissive portion. The reflective portion is configured to reflect radiant heat back towards the heat exchange block 22. The opening 32 is configured to allow radiant heat to escape relative to the reflective portion. By modulating the size of the opening 32, heat loss from the crucible may be controlled. In general, the size of the opening 32 may be modulated in any suitable manner. Examples of suitable methods of modulating the size of the opening 32 include electrical and mechanical actuators, and the like that are controlled by a controller, for example.

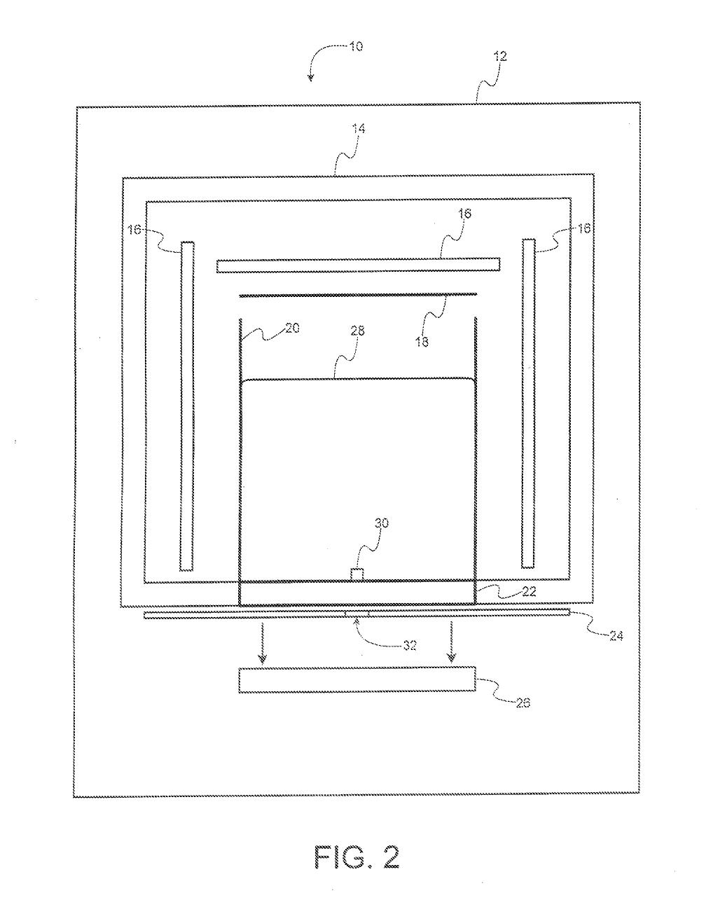

FIG. 2 is a cross sectional view of the solidification system or the BGGCSS 10 according to FIG. 1 during a solidification process. As shown in FIG. 2, the movable insulation 26 may be moved relatively away from the radiation regulator 24 and the heat exchange block 22 disposed below the crucible 20. In this manner, radiant heat may be allowed to escape from the opening 32. In FIG. 2, the opening 32 is relatively small or fully closed such that the seed crystal 30 may be formed or optionally, so that the seed crystal 30 may enlarge in a controlled manner.

In general, the size of the opening 32 may be controlled such that it is fully closed to about the same diameter as the seed crystal 30. In general, the controller may be configured to modulate the size of the opening 32 based on a predetermined time/temperature profile, temperature measurements, and the like. In an embodiment, the size of the opening 32 is controlled to be slightly (about 0% to about 90%) larger than the diameter of the seed crystal 30. In this manner, the seed crystal 30 may grow or accrete solid Si at a relatively fast rate. In another embodiment, the size of the opening 32 is controlled to be the same as the diameter of the seed crystal 30. In this manner, the seed crystal 30 may grow at a relatively slower rate and with relatively fewer defects. In yet another embodiment, the size of the opening 32 is controlled to be slightly (about 0% to about 90%) smaller than the diameter of the seed crystal 30. In this manner, the seed crystal 30 may grow at a relatively slower rate still and with relatively fewer defects.

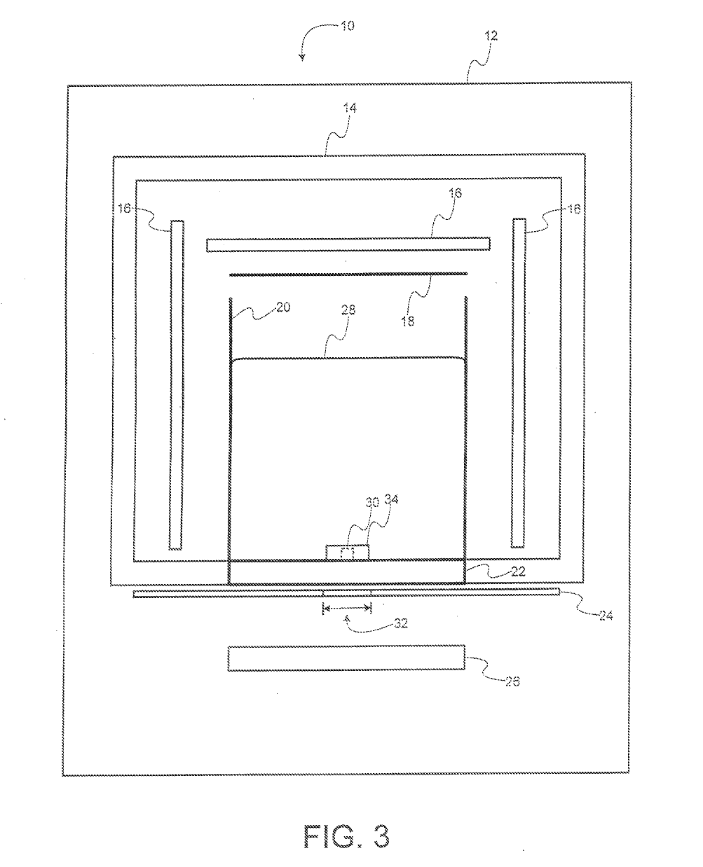

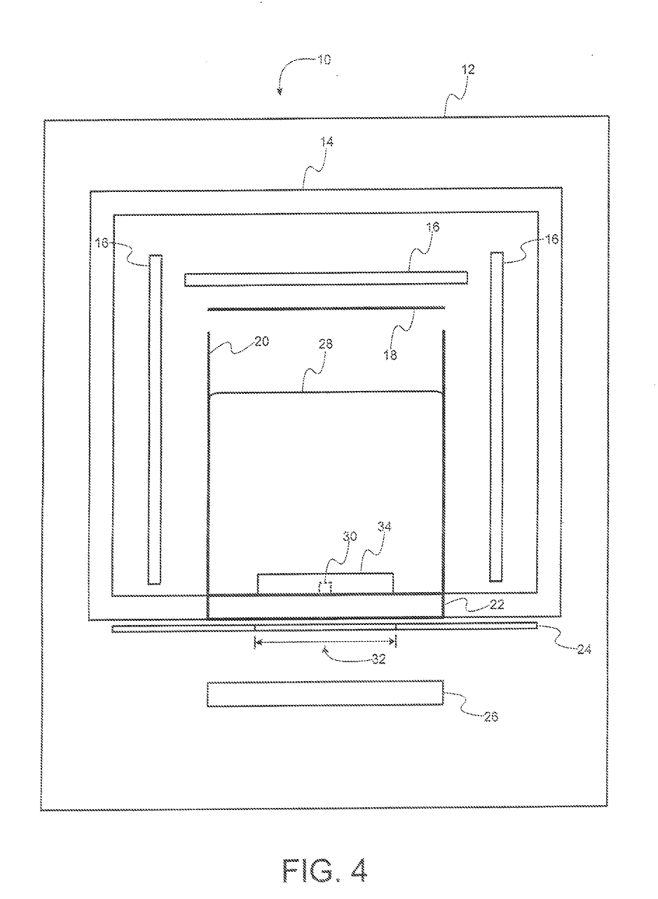

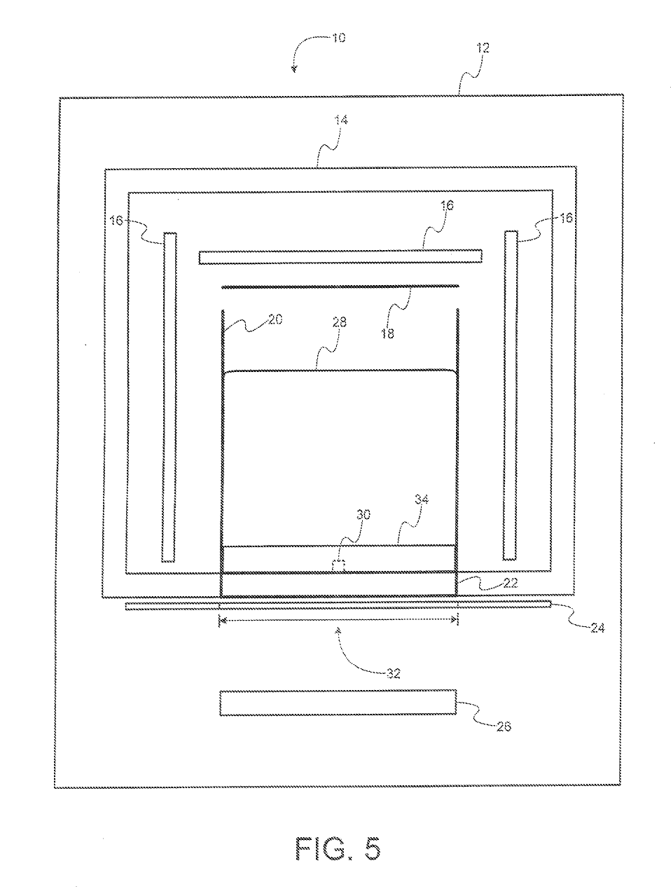

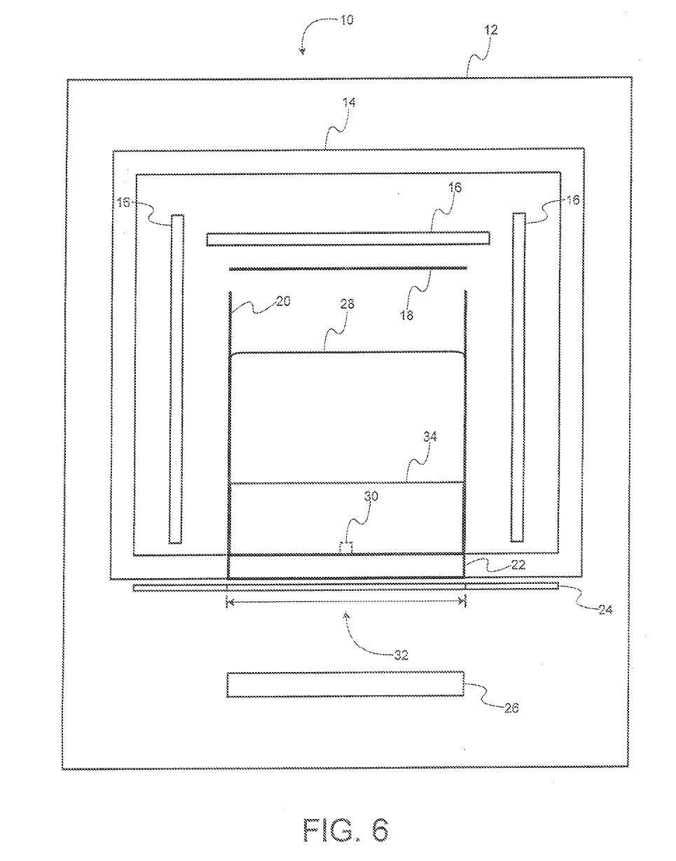

FIG. 3 is a cross sectional view of the BGGCSS 10 according to FIG. 1 during the solidification process. As shown in FIG. 3, a solid Si 34 crystal is accreted (e.g., accumulate precipitated solid Si) upon the seed crystal 30 as the opening 32 is enlarged. Also shown in FIG. 3, the solid Si 34 is generally controlled to grow outwardly along the bottom of the crucible. This outward or horizontal growth may be achieved by modulating the amount of radiant heat loss via the modulation of the movable insulation 26 and size of the opening 32. This process is shown to continue stepwise in FIGS. 4 and 5. In FIG. 6, the solid Si 34 is shown to grow vertically as heat continues to radiate from the opening 32.

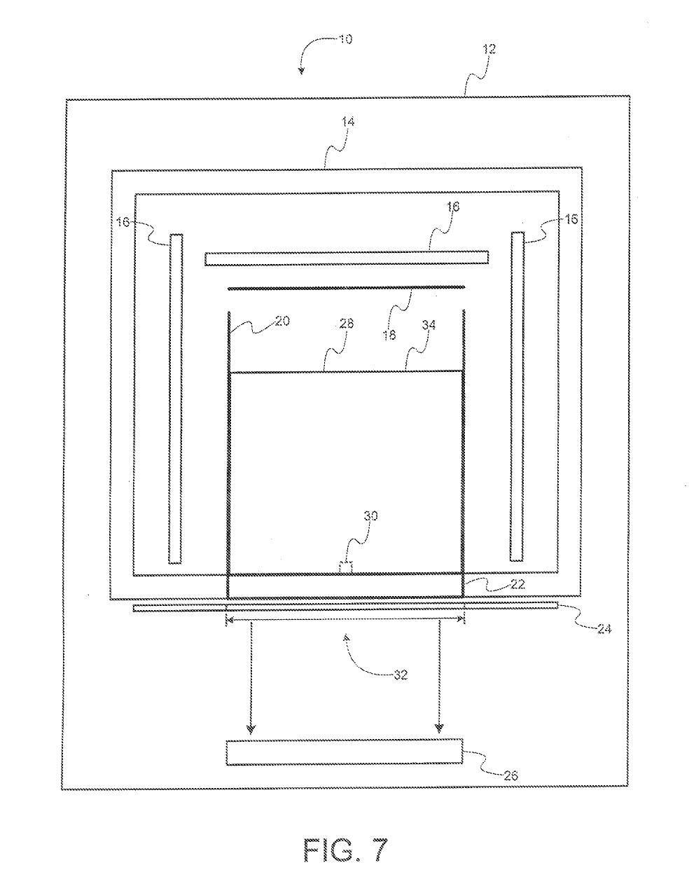

FIG. 7 is a cross sectional view of the BGGCSS 10 according to FIG. 1 during the solidification process. As shown in FIG. 7, the movable insulation 26 is moved further from the radiation regulator 24 and the heat exchange block 22 disposed below the crucible 20. In this manner, a greater amount of radiant heat may be allowed to escape from the crucible 20 and the volume of Si 28 therein to accelerate and complete solidification.

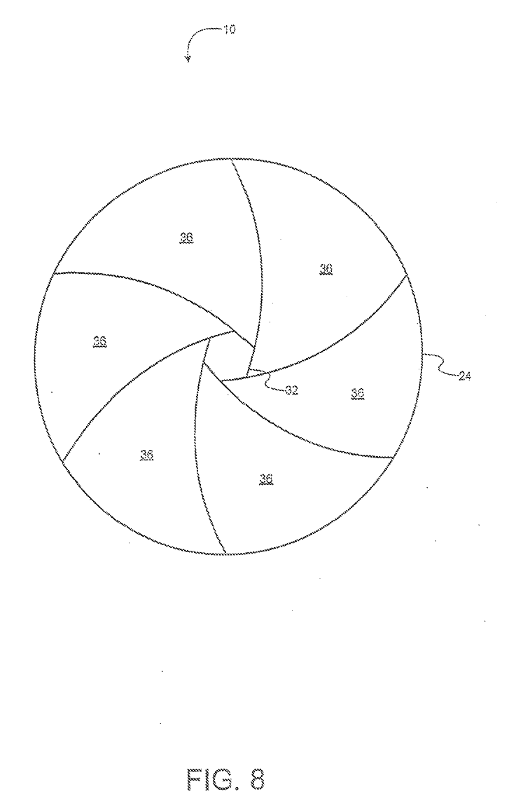

FIG. 8 is a top view of the radiation regulator 24 suitable for use with the BGGCSS 10 according to FIG. 1. As shown in FIGS. 8-10, an example of the radiation regulator 24 may operate in a well known manner similar to that of an iris diaphragm for adjusting the aperture of a camera with the opening 32 corresponding to the aperture of the iris diaphragm. In the particular example shown in FIG. 8, the radiation regulator 24 includes six shutters 36. However, the radiation regulator 24 need not includes six shutters 36, but rather, may include any suitable number of shutters 36. Suitable numbers of shutters 36 include 1, 2, 3, 4, 5, 6, 7, 8, 9, 10, 11, 12, etc. Also shown in FIG. 8, the opening 32 accounts for a relatively small portion in comparison to the total surface area of the radiation regulator 24.

Although, in general, an iris diaphragms for adjusting the aperture of a camera include overlapping shutters, the shutters 36 of the embodiment shown in FIGS. 8-10 need not be overlapping, but rather, may butt one edge against the other. In this manner, the radiation regulator 24 may be made to be relatively thinner and relatively less radiation may escape from gaps caused by the overlapping shutters 36.

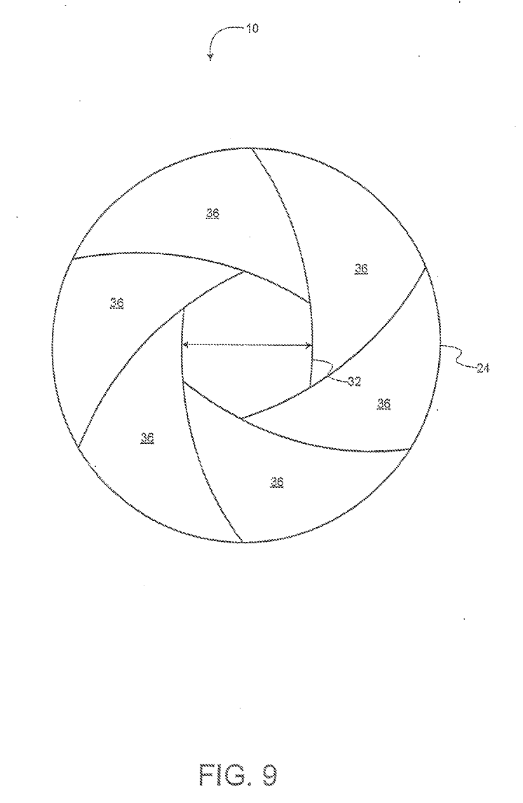

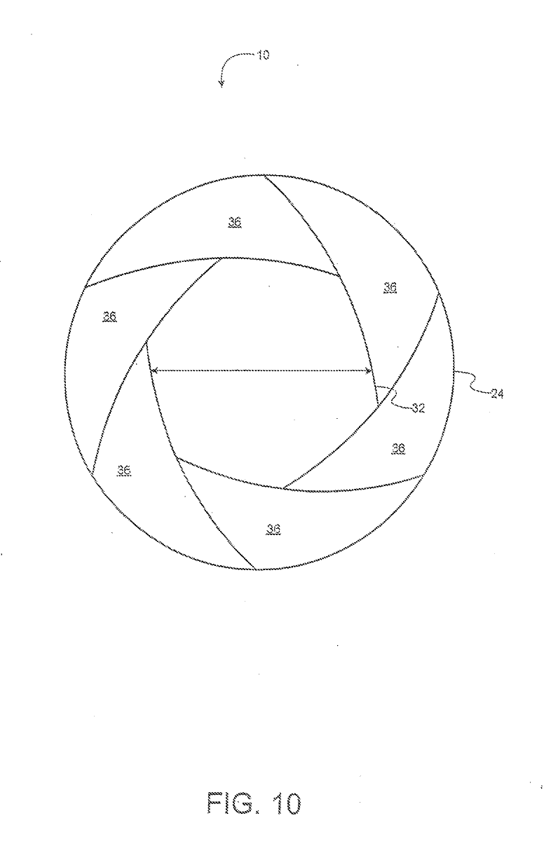

FIG. 9 is a top view of the radiation regulator 24 suitable for use with the BGGCSS 10 according to FIG. 1 in a partially open conformation. As shown in FIGS. 9 and 10, the size of the opening 32 may be modulated via the movement of the shutters 36.

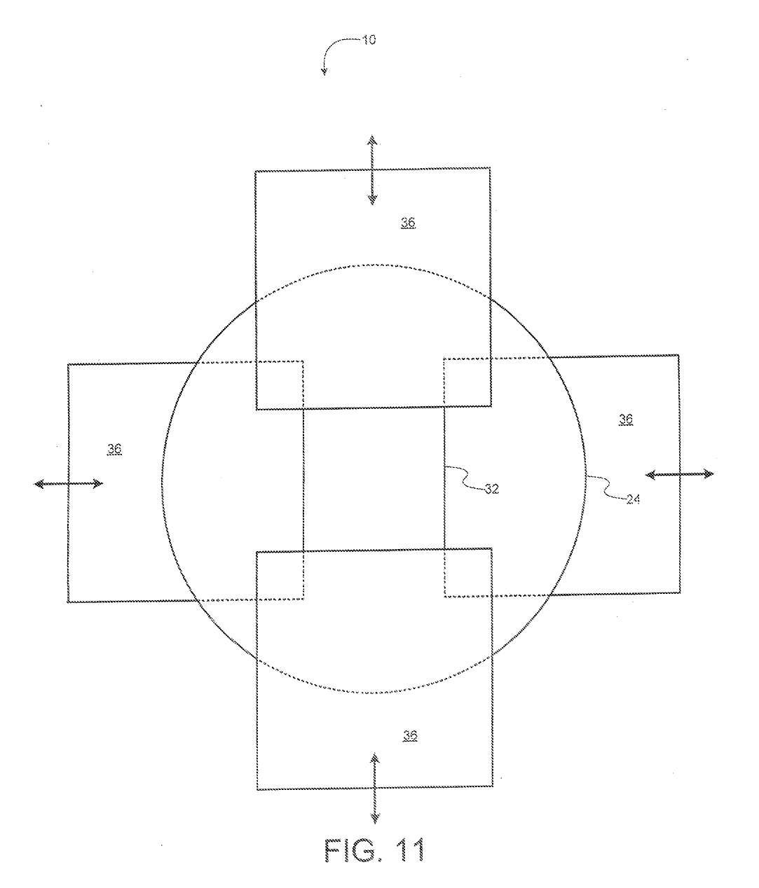

FIG. 11 is a top, hidden line, view of a radiation regulator 24 suitable for use with the BGGCSS 10 according to FIG. 1. As shown in FIG. 11, a pair of opposing shutters 36 are disposed one side of the radiation regulator 24 and a second pair of shutters 36 are disposed on a second side of the radiation regulator 24. To modulate the size of the opening 32, the shutters 36 may be controlled to move closer together and/or further apart. In the particular example shown in FIG. 11. The shutters 36 are disposed in their fully open position.

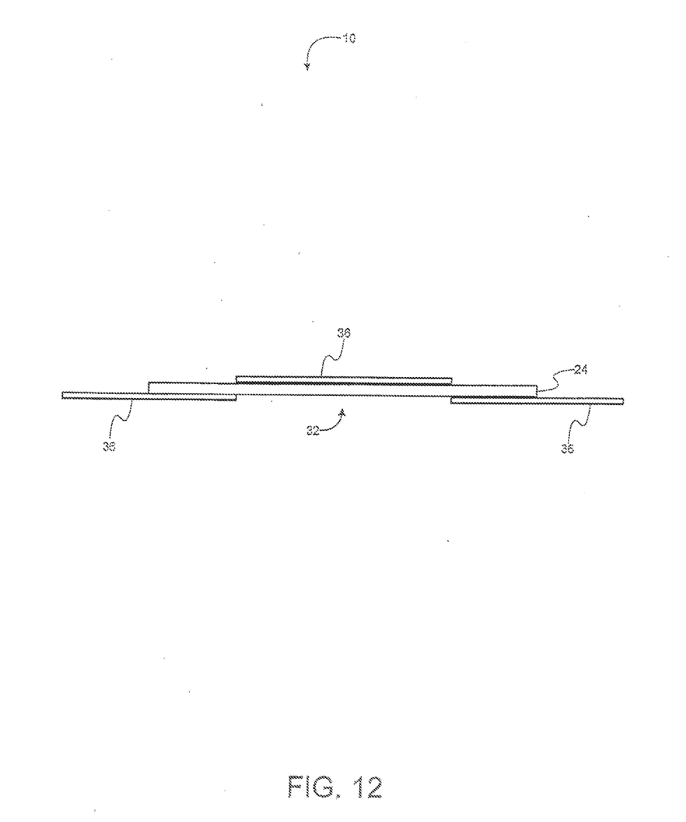

FIG. 12 is a side view of the radiation regulator 24 suitable for use with the BGGCSS 10 according to FIG. 1. As shown in FIG. 12, the shutters 36 may be in direct sliding contact with the radiation regulator 24. It is an advantage of this direct sliding arrangement that radiant heat loss may be minimized across the radiation regulator 24 and therefore concentrated at the opening 32.

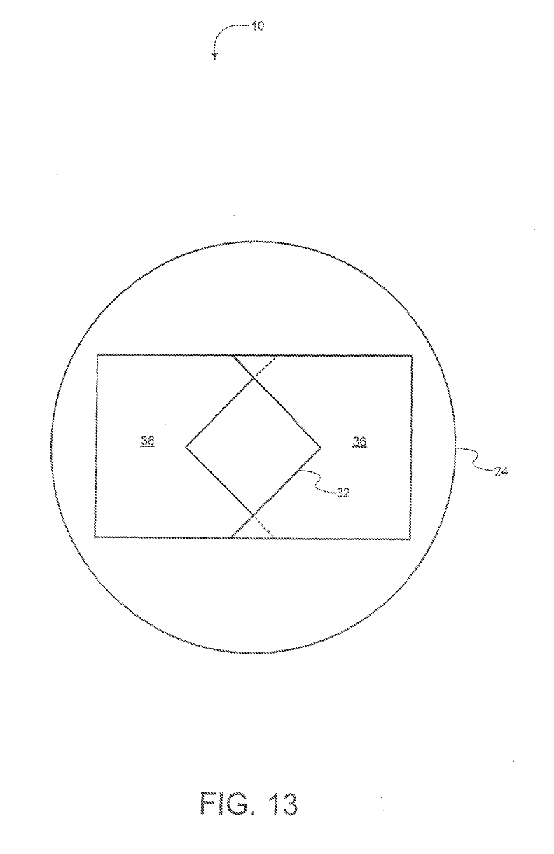

FIG. 13 is a top, hidden line view of the radiation regulator 24 according to another embodiment of the invention. As shown in FIG. 13, the regulator 24 includes a pair of the shutters 36 and each of the shutters 36 include a respective notch 38. The notches 38 are in cooperative alignment to form the opening 32. The size of the opening 32 is modulated by moving the shutters 36 relative to one another. In FIG. 13, the opening 32 is in a relatively open conformation. By moving the shutters 36 towards one another, the opening 32 is reduced in size.

Of note, although the notches 38 are shown as angular or triangular, the notches 38 need not be angular, but rather, may include any suitable shape or shapes. Examples of suitable shapes include triangular, polygonal, semi-circular, ovoid, parabolic, and the like.

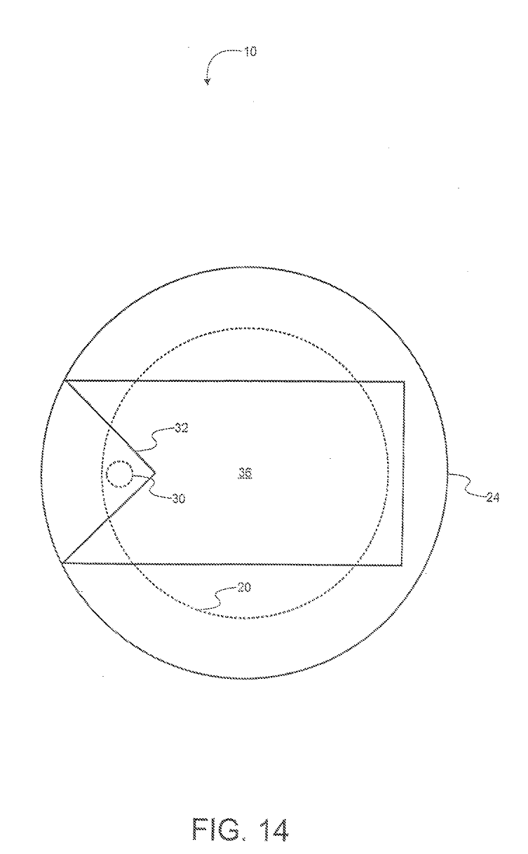

FIG. 14 is a bottom, hidden-line view of the radiation regulator 24 according to yet another embodiment of the invention. As shown in FIG. 14, the single shutter 36 includes the respective notch 38 in cooperative alignment with the seed crystal of Si 30. The seed crystal of Si 30 is disposed adjacent to the walls of the crucible 20. In the embodiment shown in FIG. 14, as the shutter 36 is moved, the portion of the opening 32 disposed below the crucible 20 is enlarged and thus the temperature of the volume of Si 28 in the vicinity of the seed crystal of Si 30 is cooled to allow the seed crystal of Si 30 to grow. It is an advantage of this embodiment that the radiation regulator 24 is relatively simpler than designs with two or more shutters 36.

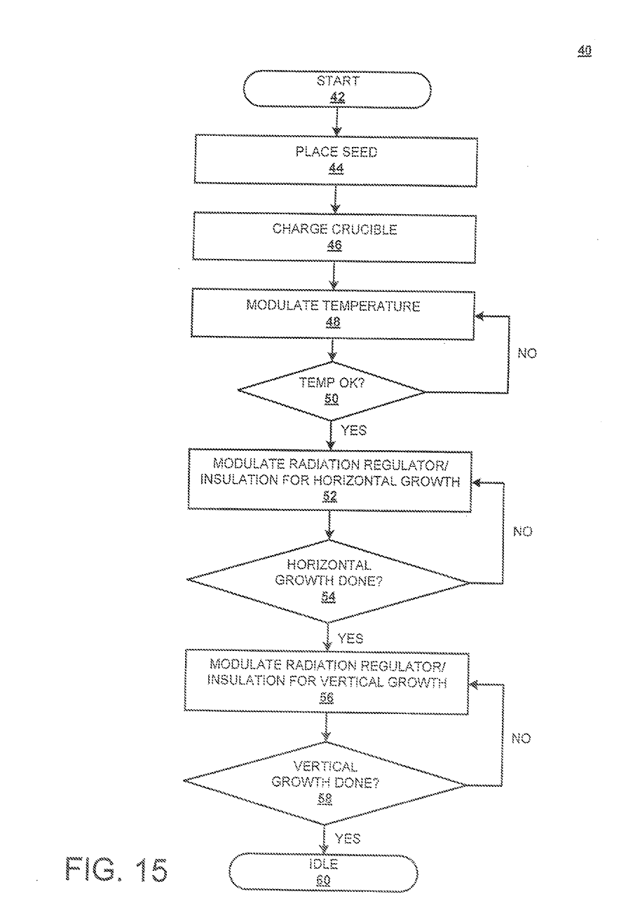

FIG. 15 is a flow diagram of a method 40 for solidifying silicon with the BGGCSS 10 according to FIG. 1. Prior to initiation of the method 40, the BGGCSS 10 may be prepared and a supply of Si may be obtained.

At step 44, the Si seed crystal 30 may, optionally, be placed within the crucible 20. In a particular example, the Si seed crystal 30 may be placed within the volume of Si 28 at the bottom center of the crucible and in cooperative alignment with the opening 32. In another example, sufficient radiant heat may be allowed to escape from the opening 32 to urge the formation of one or more seed crystals to form at the bottom center of the crucible and in cooperative alignment with the opening 32.

At step 46, the crucible 20 may be charged with the supply of Si and any suitable elements, reagents, or the like. For example, as is generally known, elements may be added to the melt to effect the electrical properties of the resulting silicon ingot and thus to any silicon wafer made therefrom. Thereafter, some or all of the charge of Si may be melted in any suitable manner. For example, the furnace chamber 12 may be controlled by a controller, for example, to heat the charge of silicon and/or the heaters 16 may be controlled to impart sufficient heat to melt the charge of silicon. The heat may be applied selectively along the crucible to melt the charge while minimizing the amount of seed crystal that is melted.

At step 48, the temperature of the volume of Si 28 may be modulated to slightly above the solidification temperature. More particularly, at or near the seed crystal of Si 30, the temperature may be modulated to a point that is above the solidification temperature and below the melting point. As is generally known, in order to assure the correct temperature is obtained, a microprocessor controller employing proportional/integral/derivative control logic in order to reduce temperature overshoot. In a particular example, the microcontroller or other such controller may be configured to reduce the heat output from the heaters 16 to reduce the temperature of the volume of Si 28.

At step 50, it is determined if the temperature of the volume of Si 28 is at the correct temperature. For example, a sensor on or near the crucible 20 may sense to temperature and/or an infrared sensor may sense the temperature of the crucible 20 and/or the temperature of the volume of Si 28. Signals from the sensor may be received by a controller and, in response to the sensed temperature(s), the controller may determine that the temperature of the volume of Si 28 is above or below a predetermined temperature. If so, the temperature of the volume of Si 28 may be modulated by the controller at step 48.

At step 52, the movable insulation 26 and/or the radiation regulator 24 are controlled to facilitate horizontal crystallization or growth of the seed crystal of Si 30 in the horizontal direction. For example, the movable insulation 26 may be moved away from the radiation regulator 24 in order to allow radiant heat to escape from the opening 32. For example, the controller may forward signals to an actuator configured to move the movable insulation 26. By controlling the distance the movable insulation 26 is moved away from the radiation regulator 24, the amount of radiant heat loss may be further controlled. In a particular example, the movable insulation 26 may be moved a first distance away from the radiation regulator 24 to allow radiant heat to escape in a relatively slow and controlled manner. However, as the bottom of the crucible becomes covered in a confluent layer of solid Si, the movable insulation 26 may be moved further away to speed solidification of the Si ingot.

Also at step 52, the radiation regulator 24 may be modulated. In general, one or more actuators controlled by the controller may be configured to move the shutters 36. For example, the shutters 36 may be controlled to open and enlarge the opening 32 and/or close to decrease the size of the opening 32 to modulate the amount of radiation heat loss. In a particular example, the radiation regulator may be controlled to open the opening 32 at a rate predetermined to coincide with the diameter of the solid Si 34 growing along the bottom of the crucible 20. In another example, based on the temperature along the bottom of the crucible 20, the diameter of the solid Si 34 may be determined and the radiation regulator 24 may be controlled to modulate the opening 32 based on the sensed diameter of the solid Si 34.

At step 54, it is determined if the horizontal growth is completed. For example, the temperature across the bottom of the crucible may be sensed and if it is below a predetermined solidification temperature, then it is determined that horizontal growth is completed. If it is determined that the horizontal growth is not completed, the movable insulation 26 and/or the radiation regulator 24 may be further modulated at step 52.

At step 56, the movable insulation 26 and/or the radiation regulator 24 are controlled to facilitate vertical crystallization or growth of the seed crystal of Si 30 in the vertical direction. For example, the movable insulation 26 may be moved further away from the radiation regulator 24 and the radiation regulator 24 may be opened further or fully in order to allow radiant heat to escape from the opening 32. In addition, the heaters may be controlled to further reduce the temperature of the crucible (particularly at or near the bottom of the crucible).

At step 58, it is determined if the vertical growth is completed. For example, the temperature along the height of the crucible may be sensed and if it is below a predetermined solidification temperature, then it is determined that vertical growth is completed. In another example, based on the temperature of the volume of Si 28 and/or a visual observation, etc., it may be determined the volume of Si 28 has not solidified. If it is determined that the vertical growth is not completed, the movable insulation 26 and/or the radiation regulator 24 may be further modulated at step 56.

If it is determined that the volume of Si 28 has solidified, the BGGCSS 10 may be controlled to idle or stop at step 60.

Following the method 40, the resulting Si ingot may be processed according to known Si ingot processing procedures.

The many features and advantages of the invention are apparent from the detailed specification, and thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described, and accordingly, all suitable modifications and equivalents may be resorted to, falling within the scope of the invention.

What is claimed is:

1. A solidification system, comprising:
a crucible configured to retain a volume of silicon;
a heater to heat the crucible, the heater being configured to provide sufficient heat to melt the volume of silicon;
an insulation to reduce heat loss from a first portion of the crucible;
a movable insulation to regulate heat loss from a second portion of the crucible; and
a radiation regulator to regulate radiant heat loss over the second portion of the crucible, the radiation regulator being configured to modulate a size of an opening in the radiation regulator through which radiant heat dissipates from.

2. The solidification system according to claim 1, further comprising:
a furnace chamber configured to retain the crucible.

3. The solidification system according to claim 1, further comprising:
a heat exchange block configured to support the crucible and allow heat to conduct therethrough.

4. The solidification system according to claim 1, further comprising:
a shield configured to cover at least a portion of the crucible.

5. The solidification system according to claim 1, further comprising:
a seed crystal of silicon disposed in the crucible.

6. The solidification system according to claim 1, wherein the radiation regulator further comprises:
a plurality of shutters operable to move relative to one another.

7. The solidification system according to claim 6, wherein the plurality of shutters includes a first pair of shutters disposed at a first side of the radiation regulator and a second pair of shutters disposed at a second side of the radiation regulator.

8. The solidification system according to claim 6, wherein the radiation regulator further comprises:
an iris diaphragm, the plurality of shutters being disposed in the iris diaphragm.

9. A radiation regulator, comprising:
a radiant heat reflective portion; and
a radiant heat transmissive portion, the radiant heat transmissive portion being operable to increase and decrease in size and the radiant heat transmissive portion being disposed in cooperative alignment with a bottom center portion of a crucible.

10. The radiation regulator according to claim 9, further comprising a plurality of shutters disposed in an iris diaphragm configuration.

11. The radiation regulator according to claim 9, further comprising a first pair of shutters disposed at a first side of the radiation regulator and a second pair of shutters disposed at a second side of the radiation regulator.

12. A method of solidifying a volume of silicon, the method comprising the steps of:
modulating a temperature of the volume of silicon between a temperature of solidification and a temperature of melting;
insulating a first portion of the volume of silicon; and
modulating a size of a radiant heat transmissive opening disposed in cooperative alignment with a second portion of the volume of silicon.

13. The method according to claim 12, further comprising:
modulating the size of the radiant heat transmissive opening to coincide with a diameter of a solidified portion of the volume of silicon.

14. The method according to claim 13, further comprising:
moving a plurality of shutters to modulate the size of the radiant heat transmissive opening.

15. The method according to claim 12, further comprising:
moving an insulation disposed around the second portion of the volume of silicon away from the second portion of the volume of silicon.

16. The method according to claim 12, further comprising:
disposing a seed crystal of silicon in the volume of silicon and in cooperative alignment with the radiant heat transmissive opening.

17. An apparatus for solidifying a volume of silicon, the apparatus comprising:
means for modulating a temperature of the volume of silicon between a temperature of solidification and a temperature of melting;
means for insulating around a first portion of the volume of silicon; and
means for modulating a size of a radiant heat transmissive opening disposed in cooperative alignment with a second portion of the volume of silicon.

18. The apparatus according to claim 17, wherein the means for modulating the size of the radiant heat transmissive opening is configured to modulate the size of the radiant heat transmissive opening to coincide with a diameter of a solidified portion of the volume of silicon.

19. The apparatus according to claim 18, further comprising:
means for moving a plurality of shutters to modulate the size of the radiant heat transmissive opening.

20. The apparatus according to claim 17, further comprising:
means for moving an insulation disposed around the second portion of the volume of silicon away from the second portion of the volume of silicon.
